(19) United States
(12) Patent Application Publication
(10) Pub. No.: US 2025/0239976 A1
(43) Pub. Date: Jul. 24, 2025

(54) MUSICAL INSTRUMENT AMPLIFICATION SYSTEM SETTINGS ADJUSTMENT

(71) Applicant: Mus, LLC., Wayzata, MN (US)

(72) Inventors: Bruce C. Larson, Tampa, FL (US); Thomas K. Just, Wayzata, MN (US)

(21) Appl. No.: 18/418,802

(22) Filed: Jan. 22, 2024

(51) Int. Cl. H03F 3/183; G10H 1/00; G10H 1/34

(52) U.S. Cl. CPC H03F 3/183; G10H 1/0008; G10H 1/348; G10H 2220/265; H03F 2200/03

(57) ABSTRACT

Systems, methods, and apparatuses are provided for musical instrument amplifier settings adjustment. A musical instrument amplifier comprises a manual interface configured to adjust actuators of the musical instrument amplifier, settings of the musical instrument amplifier, or both. The musical instrument amplifier also comprises communication circuitry configured to receive an input communication signal from an external device to adjust the musical instrument amplifier actuators and send an output communication signal from the musical instrument amplifier to the external device in response to receipt of the input communication signal and/or a manual interface input. The musical instrument amplifier further includes control circuitry configured to adjust the musical instrument amplifier actuators, the setting of the musical instrument amplifier, or both based on the input communication signal. Adjusting the musical instrument amplifier actuators adjusts external device actuators and adjusting the external device actuators adjusts the musical instrument amplifier actuators.

### TECHNICAL FIELD

Embodiments of the disclosure relate generally to a musical instrument amplification system, and more specifically, relate to musical instrument amplifier settings adjustment.

### BACKGROUND

A musical instrument amplifier (e.g., amplifier) is an electronic device that converts an audible or electronic signal of a musical instrument into a larger electronic signal to input into a loudspeaker. An amplifier is used with a musical instrument such as an electric guitar, an electric bass, an electric organ, a synthesizer, or a drum machine, among other possible musical instruments, to convert the signal from the pickup (with guitars, other string instruments, and some keyboards) or another sound source (e.g., a synthesizer's signal) into an electronic signal that has enough power, due to being routed through a power amplifier, to drive one or more loudspeakers that can be heard by performers and the audience.

Amplifiers come in two main forms, a combo amplifier and an amplifier head. The combo amplifier contains both the amplifier and the loudspeakers in a single unit. An amplifier head is an amplifier that is separate from the loudspeakers and is coupled to loudspeakers with cables. The amplifier head is commonly placed on top of one or more loudspeaker enclosures. The amplifier head and loudspeaker enclosures together form an amplifier stack. An amplifier stack consisting of a head and two loudspeaker cabinets is sometimes called a double stack or a “full stack.”

### BRIEF DESCRIPTION OF THE DRAWINGS

FIG. 1 is a schematic view of a musical instrument amplifier in accordance with an embodiment of the present disclosure.

FIG. 2 is a schematic view of a musical instrument peripheral in accordance with an embodiment of the present disclosure.

FIG. 3 is a schematic view of a musical instrument amplification system in accordance with an embodiment of the present disclosure.

### DETAILED DESCRIPTION

The present disclosure includes apparatuses, methods, and systems for musical instrument amplification system settings adjustment. An embodiment includes a musical instrument amplifier comprising a manual interface configured to adjust one or more actuators of the musical instrument amplifier, settings of the musical instrument amplifier, or both. The musical instrument amplifier can also comprise communication circuitry configured to receive an input communication signal from an external device to adjust the one or more musical instrument amplifier actuators and send an output communication signal from the musical instrument amplifier to the external device in response to receipt of the input communication signal and/or manual interface input. The musical instrument amplifier can further comprise control circuitry configured to adjust the one or more musical instrument amplifier actuators, the settings of the musical instrument amplifier, or both based on the input communication signal, wherein adjusting one or more musical instrument amplifier actuators adjusts one or more external device actuators and adjusting the one or more external device actuators adjusts the one or more musical instrument amplifier actuators.

Musical instrument amplifiers can be coupled to musical instrument peripherals. As used herein, the term “musical instrument peripherals” refers to a musical device or musical component used to transfer signals into and out of the musical instrument amplifier. Non-limiting examples of musical instrument peripherals can include, but are not limited to, a foot pedal, a keyboard, an electric guitar, a drum set, etc. A musical instrument amplifier can include settings that control characteristics of the sound output by the amplifier. The settings can be adjusted using a manual interface of the amplifier or adjusted based on a signal received from a peripheral.

In previous approaches, the position of the manual interface of the amplifier is not synchronized with the position of the manual interfaces of the one or more peripherals coupled to the amplifier. For example, when an amplifier manual interface is moved in one direction to achieve a certain setting and a manual interface of a peripheral coupled to the amplifier is moved in the opposite direction to achieve a different setting, the position of the amplifier manual interface does not change in response to the peripheral manual interface changing. Further moving the amplifier manual interface in the same direction can cause the amplifier manual interface to reach the end of the range of movement of the amplifier manual interface in that direction. This can prevent the amplifier manual interface from subsequently moving further in that direction to achieve a desired setting for the amplifier.

Embodiments of the present disclosure, however, can monitor the position of each manual interface, detect changes in the positions of each manual interface, and change a manual interface of either the amplifier or the peripheral to correspond to the position of the manual interface of the other of the amplifier or peripheral. For example, when an amplifier manual interface changes position, the amplifier can send a signal to the peripheral to change the position of the peripheral manual interface to correspond to the position of the amplifier manual interface. Further, when a peripheral manual interface changes position, the peripheral can send a signal to the amplifier to change the position of the amplifier manual interface to correspond to the position of the peripheral manual interface. Automatically changing the position of the peripheral manual interface to correspond to the position of the amplifier manual interface, and automatically changing the position of the of the amplifier manual interface to correspond to the position of the peripheral manual interface can prevent a manual interface from being unable to further change its position to adjust a setting due to being at a limit of the manual interface's range of movement. Furthermore, this can provide synchronization of manual interface inputs which can give a user valuable information about the present state of the amplifier settings and the position of each manual interface. As used herein, the term “synchronization” refers to the position of the amplifier manual interface input changing to correspond to the position of a musical instrument peripheral manual interface input and the position of a musical instrument peripheral manual interface input changing to correspond to a position of the musical instrument amplifier manual interface.

As used herein, “a,” “an,” or “a number of” can refer to one or more of something, and “a plurality of” can refer to two or more such things. For example, a memory device can refer to one or more memory devices, and a plurality of memory devices can refer to two or more memory devices. Additionally, the designator “N” as used herein, particularly with respect to reference numerals in the drawings, indicates that a number of the particular feature so designated can be included with a number of embodiments of the present disclosure.

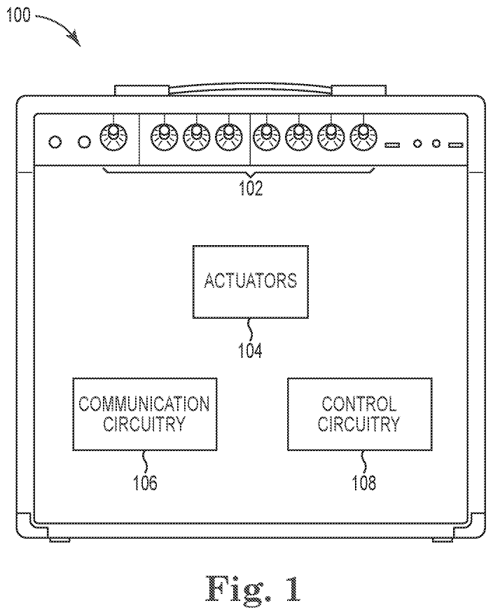

FIG. 1 is a schematic view of a musical instrument amplifier in accordance with an embodiment of the present disclosure. FIG. 1 includes a musical instrument amplifier 100 comprising a manual interface 102, actuators 104, communication circuitry 106, and control circuitry 108. In some embodiments, the manual interface 102 can include, but is not limited to, knobs, buttons, sliders, and/or switches on the musical instrument amplifier 100.

The manual interface 102 can be configured to adjust one or more actuators 104 of the musical instrument amplifier 100, settings of the musical instrument amplifier 100, or both. The one or more actuators 104 and settings can be adjusted by changing the position of the manual interface 102 from a first position to a second position. For example, a manual interface input can adjust the position of the manual interface 102 by turning at least one of the knobs from a first position to a second position, sliding at least one of the sliders from a first position to a second position, and/or flipping at least one of the switches from a first position to a second position. Adjusting the position of the manual interface 102 can also include pressing a button (e.g., a pushbutton) on the manual interface.

The settings of the musical instrument amplifier 100 can include, but are not limited to, volume, gain, treble, midrange, and bass. The volume setting on the musical instrument amplifier 100 determines the volume of the sound being output by the musical instrument amplifier 100. Some musical instrument amplifiers 100 can have more than one channel and can control the volume of each of those channels separately. Further, some musical instrument amplifiers 100 can have a master volume control which determines the volume of every channel. Adjusting the master volume channel can adjust the volume of every channel simultaneously.

The gain setting of the musical instrument amplifier 100 determines the amount of distortion in the tone of the sound being output by the musical instrument amplifier 100. As used herein, the term “distortion” refers to audio signal processing used to alter the sound being output by a musical instrument amplifier 100. The treble setting can determine how much the musical instrument amplifier 100 emphasizes high frequency sounds, the midrange setting can determine how much the musical instrument amplifier 100 emphasizes midrange frequency sounds, and the bass setting can determine how much the musical instrument amplifier 100 emphasizes low frequency sounds.

In some embodiments, the manual interface 102 can include one or more knobs, buttons, sliders, and/or switches that are each associated with one or more actuators 104. As used herein, the term “actuator” refers to a component of a machine that is responsible for moving and controlling a mechanism and/or system, changing the settings and/or characteristics of a mechanism and/or system, or both. An actuator 104 can influence or determine settings of the musical instrument amplifier 100. Alternatively, an actuator 104 can achieve physical movements by converting energy, such as electrical energy and/or hydraulic energy, into mechanical force. In some embodiments, the motion achieved by the actuator 104 can be a rotary movement or a linear movement.

In some embodiments, the one or more actuators 104 can be one or more stepper motors. As used herein, the term “stepper motor” refers to a brushless direct current (DC) motor that divides a full rotation into a number of equal steps. Stepper motors can convert a train of input pulses into a precisely defined increment in the shaft's rotational position. Each pulse can rotate the shaft though a fixed angle.

In some embodiments, the actuator 104 can be one or more servo motors. As used herein, the term “servo motor” refers to a rotary actuator or linear actuator that allows for precise control of angular or linear position, velocity, and acceleration. A servo motor can use position feedback to control its motion and final position. For example, if the position of a servo motor differs from a position corresponding to a command, the servo motor can rotate until the position of the servo motor matches the position corresponding to the command.

In some embodiments, the one or more actuators 104 can be one or more potentiometers. As used herein, the term “potentiometer” refers to a manually adjustable variable resistor with three terminals. In a potentiometer, two of the terminals can be coupled to opposite ends of a resistive element and the third terminal can be coupled to a sliding contact that moves over the resistive element. In some embodiments, only two of the terminals of the potentiometer may be utilized, with the remaining terminal connected in common with another terminal (e.g., connected to the same element at another terminal) or left unconnected. For example, the third terminal of the potentiometer can either be left unconnected or connected to either the first terminal or the second terminal.

In some embodiments, one or more actuators 104 can be coupled to the manual interface 102. For example, a knob of the manual interface 102 can be coupled to a shaft of a potentiometer that is functioning as an actuator 104. In this example, turning the knob of the manual interface 102 can turn the shaft of the potentiometer that is functioning as the actuator 104. Turning the shaft of the potentiometer can change the resistance of the potentiometer and changing the resistance of the potentiometer can change the voltage that is output by the potentiometer in some application circuits. Therefore, turning a knob of the manual interface 102 that is coupled to a shaft of a potentiometer functioning as an actuator 104 can change a setting of the musical instrument amplifier 100 when the strength of that setting depends on the amount of voltage output by the potentiometer.

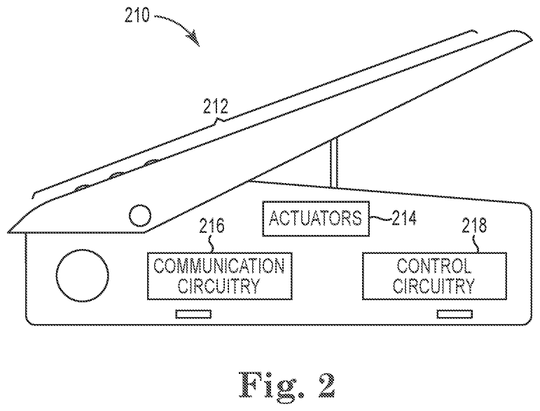

The musical instrument amplifier 100 can include communication circuitry 106 configured to receive an input communication signal from an external device (e.g., musical instrument peripheral 210 in FIG. 2) to adjust the one or more actuators 104. In some embodiments, the external device can be a musical instrument peripheral such as one or more foot pedals. Further, in some embodiments, at least one of the knobs of the manual interface 102 can change from a first position to a second position in response to receipt of the input communication signal from the external device. Therefore, one or more actuators 104 and/or settings of the musical instrument amplifier 100 can change in response to receiving the input communication signal from the external device.

Communication circuitry 106 can be configured to send an output communication signal from the musical instrument amplifier 100 to one or more external devices in response to receipt of the input communication signal and/or a manual interface input. A manual interface input can be an action that changes the manual interface 102 from the first position to a second position. The communication circuitry 106 can be configured to send and/or receive signals by wired or wireless (e.g., radio, optical, ultrasound) communication.

The musical instrument amplifier 100 can include control circuitry 108 configured to adjust the one or more actuators 104, the settings of the musical instrument amplifier 100, or both, based on the input communication signal. In some embodiments, the one or more musical instrument amplifier actuators 104 can be coupled to the musical instrument amplifier manual interface 102 such that movement of the musical instrument amplifier actuators 104 corresponds to movement of the musical instrument amplifier manual interface 102 and movement of the musical instrument amplifier manual interface 102 corresponds to movement of the musical instrument amplifier actuators 104. In some embodiments, adjusting the one or more musical instrument actuators 104 can adjust one or more external device actuators and adjusting the one or more external device actuators can adjust the one or more musical instrument amplifier actuators 104, external device actuators of different external devices, or both. Further, the one or more musical instrument amplifier actuators 104 can adjust settings of the musical instrument amplifier 100. In some embodiments, the musical instrument amplifier 100 can include one or more position sensors (not pictured) to monitor one or more positions of the manual interface 102, the one or more actuators 104, the one or more settings of the musical instrument amplifier 100, or any combination thereof. The one or more position sensors can communicate the positions of the manual interface 102 and one or more actuators 104 to the control circuitry 108. This communication can allow the control circuitry 108 to accurately change the positions of the manual interface 102 and actuators 104 from their current positions to second positions based on an input communication signal from an external device. This communication can also allow the musical instrument amplifier control circuitry 108 and musical instrument amplifier communication circuitry 106 to communicate the positions of the musical instrument amplifier manual interface 102 and one or more musical instrument amplifier actuators 104 to an external device.

FIG. 2 is a schematic view of a musical instrument peripheral in accordance with an embodiment of the present disclosure. The musical instrument peripheral 210 can include a musical instrument manual interface 212, one or more musical instrument actuators 214, communication circuitry 216, and control circuitry 218.

As previously stated, the musical instrument peripheral 210 can be a foot pedal, an electric guitar, a keyboard, and a drum set, etc. The manual interface 212 of the musical instrument peripheral 210 can change depending on the type of peripheral. For example, the manual interface of a foot pedal can be one or more surfaces of the foot pedal, the manual interface of an electric guitar can be the knobs, dials, switches, levers, or strings of the electric guitar, the manual interface of a keyboard can be the keys, buttons, switches, knobs, surfaces, or joysticks of the keyboard, and a manual interface of a drum set can be one or more surfaces of the drum set.

In some embodiments, the manual interface 212 of the musical instrument peripheral 210 can be configured to adjust one or more musical instrument peripheral actuators 214, one or more settings of the musical instrument peripheral 210, or both. Further, one or more musical instrument peripheral actuators 214 can be configured to adjust a position of the musical instrument peripheral 210, the one or more settings of the musical instrument peripheral 210, or both, based on a manual interface input. In some embodiments, the manual interface input can be a force applied to the manual interface 212. For example, if the musical instrument peripheral 210 is a foot pedal, the manual interface input can be a force that depresses the manual interface 212 towards a bottom surface of the musical instrument peripheral 210. In some embodiments, that force can be the force of someone stepping on the manual interface 212.

The one or more musical instrument peripheral actuators 214 can be coupled to the musical instrument peripheral manual interface 212 such that movement of the musical instrument peripheral actuators 214 corresponds to movement of the musical instrument peripheral manual interface 212 and the movement of the musical instrument peripheral manual interface 212 corresponds to the movement of the musical instrument peripheral actuators 214. In some embodiments, an actuator 214 can change from a first position to a second position in response to a force being applied to a manual interface 212. The amount of movement of the musical instrument peripheral manual interface 212 that would cause one or more musical instrument peripheral actuators 214 to change from a first position to a second position can depend on the type of musical instrument peripheral 210 (e.g., foot pedal). For example, when the musical instrument peripheral 210 is a foot pedal, one type of foot pedal can include actuators (e.g., musical instrument peripheral actuators 214) that can change from a first position to a second position only in response to the musical instrument peripheral manual interface 212 (e.g. surface of a foot pedal) depressing completely down to a bottom surface of the foot pedal. In a second type of foot pedal, the one or more actuators can change from a first position to a second position when a manual interface of the foot pedal is depressed to a certain depth before reaching the bottom surface of the foot pedal.

In some embodiments, there can be multiple depths to which the musical instrument peripheral manual interface 212 can be depressed to cause the one or more musical instrument peripheral actuators 214 to change from a first position to the second position. Further, in embodiments with multiple depths to which the musical instrument peripheral manual interface 212 can be depressed to cause the one or more musical instrument peripheral actuators 214 to change positions, each depth can correspond to a different movement of the one or more musical instrument peripheral actuators 214. For example, depressing the musical instrument peripheral manual interface 212 to the first depth can cause the one or more musical instrument peripheral actuators 214 to move from a first position to a second position and depressing the musical instrument peripheral manual interface 212 to a second depth can cause the one or more musical instrument peripheral actuators 214 to move from a second position to a third position. In some embodiments, each position of the actuator can correspond to a different configuration of settings of the musical instrument amplifier (e.g., musical instrument amplifier 100 of FIG. 1). For example, a first position of the one or more musical instrument peripheral actuators 214 can correspond to a first setting configuration, a second position of the one or more musical instrument peripheral actuators 214 can correspond to a second setting configuration, and a third position of the one or more musical instrument peripheral actuators 214 can correspond to a third setting configuration.

Further, in some embodiments, a continuous range of positions of the one or more musical instrument peripheral actuators 214 can correspond to a continuous range of setting configurations of the musical instrument amplifier (e.g., musical instrument amplifier 100 of FIG. 1). For example, when the musical instrument peripheral 210 is a foot pedal, the depth to which the musical instrument peripheral manual interface 212 is depressed to cause the one or more musical instrument peripheral actuators 214 to change position can correspond to a specific point in a continuous range of musical instrument peripheral settings, which can in turn correspond to a specific point in a continuous range of musical instrument amplifier settings (e.g. volume level, bass level, treble level, tone, etc.). In other examples, the musical instrument peripheral 210 can have a different musical instrument peripheral manual interface 212 (e.g., a knob, lever, slider, joystick, etc.) which can also have a discrete or continuous range of positions.

The musical instrument peripheral 210 can include communication circuitry 216 configured to receive an input communication signal from an external device to adjust the one or more musical instrument peripheral actuators 214, a setting of the musical instrument peripheral 210, or both. In some embodiments, the external device, from the view of the musical instrument peripheral 210, can be the musical instrument amplifier (e.g., musical instrument amplifier 100 in FIG. 1) or another musical instrument peripheral. Further, the communication circuitry 216 can be configured to send an output communication signal from the musical instrument peripheral 210 the external device. In some embodiments, the output communication signal can be sent from the musical instrument peripheral 210 to the external device in response to receipt of the manual interface input.

The control circuitry 218 can be configured to adjust one or more musical instrument peripheral actuators 214, the position of the musical instrument peripheral manual interface 212, the settings of the musical instrument peripheral 210, or any combination thereof based on an input communication signal. The input communication signal can be a signal received by the musical instrument peripheral 210 from the external device. In some embodiments, adjusting the one or more musical instrument peripheral actuators 214 can adjust one or more external device actuators (e.g., actuators 104 in FIG. 1) and adjusting the one or more external device actuators can adjust the one or more musical instrument peripheral actuators 214. In some embodiments, the musical instrument peripheral 210 can include one or more position sensors (not pictured) configured to monitor a position of the musical instrument peripheral manual interface 212, the one or more musical instrument peripheral actuators 214, a setting of the musical instrument peripheral 210, or any combination thereof. The position sensor(s) can communicate the positions of the musical instrument peripheral manual interface 212 and one or more musical instrument peripheral actuators 214 to the musical instrument peripheral control circuitry 218. This can allow the musical instrument peripheral control circuitry 218 to accurately change the positions of the musical instrument manual interface 212 and musical instrument peripheral actuators 214 from their current positions to second positions based on an input communication signal from an external device. This can also allow the musical instrument peripheral control circuitry 218 and musical instrument peripheral communication circuitry 216 to communicate the positions of the musical instrument peripheral manual interface 212 and one or more musical instrument peripheral actuators 214 to an external device.

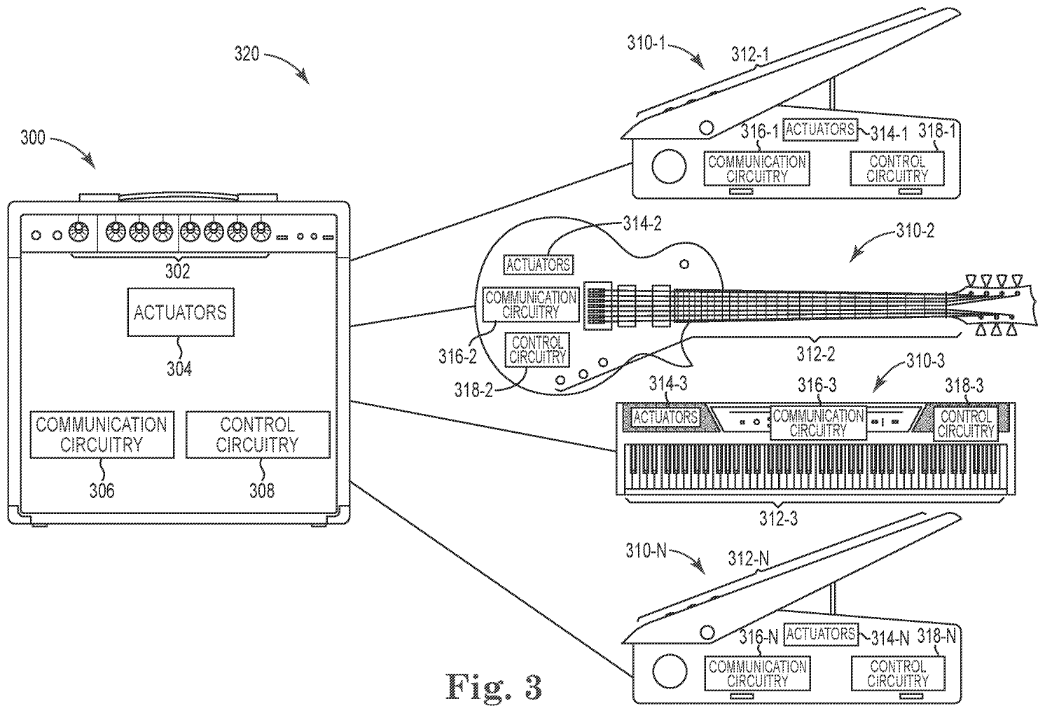

FIG. 3 is a schematic view of a musical instrument amplification system in accordance with an embodiment of the present disclosure. FIG. 3 includes a musical instrument amplifier 300 and musical instrument peripherals 310-1, 310-2, 310-3, . . . , 310-N (individually or collectively referred to as musical instrument peripherals 310). The musical instrument amplifier 300 can include a musical instrument amplifier manual interface 302, musical instrument amplifier actuators 304, musical instrument amplifier communication circuitry 306, and musical instrument amplifier control circuitry 308.

The musical instrument amplification system 320 can include a musical instrument amplifier 300 coupled to one or more musical instrument peripherals 310. In some embodiments, the musical instrument amplifier 300 can be coupled to the one or more musical instrument peripherals 310 via wired connections and/or wireless connections. More specifically, the musical instrument amplifier 300 can be coupled to the one or more musical instrument peripherals 310 via electrical wires and/or wireless communication, such as, but not limited to, radio wave communication, optical communication, or ultrasound communication. In some embodiments, radio wave communication, optical communication, and ultrasound communication can include transferring data via radio waves, light signals, or sound waves, respectively, between the musical instrument amplifier 300 and the one or more musical instrument peripherals 310, as well as between the one or more musical instrument peripherals 310. Each musical instrument peripheral 310 can include one or more musical instrument peripheral actuators 314-1, 314-2, . . . 314-N (individually or collectively referred to as musical instrument peripheral actuators 314) configured to adjust a position and/or setting of the musical instrument peripheral 310 based on a musical instrument peripheral manual interface input received by a musical instrument peripheral manual interface 312-1, 312-2, 312-3, . . . , 312-N (individually or collectively referred to as musical instrument peripheral manual interface 312). The musical instrument peripheral manual interface 312 can change based on the type of musical instrument peripheral 310. For example, the musical instrument manual interface 312-1 for the musical instrument peripheral 310-1 (e.g., a foot pedal), can be a surface of the musical instrument peripheral 310-1. The musical instrument peripheral manual interface 312-2 for the musical instrument peripheral 310-2 (e.g., a guitar) can be the knobs, switches, dials, levers, strings, etc. of the musical instrument peripheral 310-2. The musical instrument peripheral manual interface 312-3, for musical instrument peripheral 310-3 (e.g., a keyboard) can be the keys, buttons, joysticks, surfaces (touch interfaces), etc. of the musical instrument peripheral 310-3.

A musical instrument peripheral 310 can include musical instrument peripheral communication circuitry 316-1, 316-2, 316-3, . . . , 316-N (individually or collectively referred to as musical instrument peripheral communication circuitry 316) configured to receive, from the musical instrument amplifier 300, an input communication signal for the musical instrument peripheral 310 to adjust the position of the musical instrument peripheral manual interface 312. The communication circuitry 316 can further be configured to send an output communication signal from the musical instrument peripheral 310 to the musical instrument amplifier 300 to adjust a position of a musical instrument amplifier manual interface 302. Furthermore, the musical instrument peripheral communication circuitry 316 can be configured to receive, from a different musical instrument peripheral 310, an input communication signal for the musical instrument peripheral 310 to adjust the position of the musical instrument peripheral manual interface 312, or send an output communication signal from the musical instrument peripheral 310 to one or more other musical instrument peripherals 310 to adjust a position of a musical instrument peripheral manual interface 312 of the one or more other musical instrument peripherals 310. The musical instrument peripheral communication circuitry 316 can be configured to send and/or receive signals by wired or wireless communication.

The musical instrument peripherals 310 can include musical instrument peripheral control circuitry 318-1, 318-2, 318-3, . . . , 318-N (individually or collectively referred to as musical instrument peripheral control circuitry 318) configured to adjust the position of the musical instrument peripheral 310 based on signals from the musical instrument peripheral communication circuitry 316. More specifically, musical instrument peripheral control circuitry 318 can be configured to adjust a position of the musical instrument peripheral manual interface 312 based on the position of the musical instrument amplifier manual interface 302 or a different musical instrument peripheral manual interface 312. In some embodiments, the first position of the musical instrument peripheral manual interface 312-1 can be an upright position in which the musical instrument peripheral manual interface 312-1 is a maximum distance from the bottom of the musical instrument peripheral 310-1 within the range of motion of the musical instrument peripheral manual interface 312-1.

In some embodiments, the position of the musical instrument peripheral manual interface 312-1 can change based on the musical instrument amplifier manual interface 302 because one or more musical instrument peripheral actuators 314-1, 314-2, 314-3, . . . , 314-N (individually or collectively referred to as musical instrument peripheral actuators 314) can change based on the position of the musical instrument amplifier actuator 304. For example, one or more musical instrument peripheral actuators 314 can change from a first musical instrument peripheral actuator position to a second musical instrument peripheral actuator position when the one or more musical instrument amplifier actuators 304 change from a first musical instrument amplifier actuator position to a second musical instrument amplifier actuator position, or a musical instrument amplifier setting changes from a first musical instrument amplifier setting to a second musical instrument amplifier setting, or both.

In some embodiments, changing the one or more musical instrument amplifier manual interfaces 302 and/or musical instrument peripheral manual interfaces 312 from a first musical instrument manual interface position to a second musical instrument manual interface position can energize the musical instrument amplification system 320. As used herein, the term “energizing” refers to supplying power to the musical instrument amplifier actuators 304 and/or the musical instrument peripheral actuators 314 to cause a change in the position of the musical instrument amplifier actuators 304, musical instrument peripheral actuators 314, musical instrument amplifier manual interface 302, and/or musical instrument peripheral manual interface 312. The term “energizing” further refers to increasing a resistance to movement of the musical instrument amplifier actuators 304, musical instrument peripheral actuators 314, musical instrument amplifier manual interface 302, and/or musical instrument peripheral manual interface 312 due to manual inputs to the musical instrument amplifier manual interface 302 and/or the musical instrument peripheral manual interface 312.

In some embodiments, the musical instrument amplification system 320 can increase a resistance to movement of the one or more musical instrument amplifier actuators 304 from a first musical instrument amplifier actuator resistance to a second musical instrument amplifier actuator resistance in response to the one or more musical instrument peripheral manual interfaces 312 and or musical instrument peripheral actuators 314 energizing the musical instrument amplification system 320. The change in the resistance of the musical instrument amplifier actuators 304 to movement may cause a corresponding change in the resistance to movement of a musical instrument amplifier manual interface 302. For example, stepping on the musical instrument peripheral manual interface 312-1 can change the musical instrument peripheral actuators 314-1 from a first musical instrument peripheral actuator position to a second musical instrument peripheral actuator position. As the musical instrument peripheral actuators 314-1 change from a first musical instrument peripheral actuator position to a second musical instrument peripheral actuator position, the musical instrument peripheral communication circuitry 316-1 can output a signal to the musical instrument amplifier 300 to energize and change the musical instrument amplifier actuators 304 to correspond to the position of the musical instrument peripheral actuators 314-1. The change in the musical instrument amplifier actuators 304 can be configured to cause a corresponding change in the position of the musical instrument amplifier manual interface 302.

To change the position of the musical instrument amplifier actuators 304 to correspond to the position of the musical instrument peripheral actuators 314-1, the musical instrument peripheral actuators 314-1 can energize the musical instrument amplification system 320. In some embodiments, energizing the musical instrument amplification system 320 can increase a resistance of musical instrument amplifier actuators 304 and musical instrument peripheral actuators 314-2, 314-3, . . . , 314-N to movement that is caused by inputs received by the musical instrument amplifier manual interface 302 and/or the musical instrument peripheral manual interfaces 312-2, 312-3, . . . , 312-N. This can prevent any other input or signal from changing the position of the musical instrument amplifier actuators 304 and the musical instrument amplifier peripheral actuators 314-2, 314-3, . . . , 314-N until the musical instrument amplifier actuators 304, musical instrument amplifier manual interface 302, musical instrument peripheral actuators 314-1 and musical instrument peripheral manual interface 312-1 have completed their change of position. For example, subsequent inputs into the musical instrument amplifier manual interface 302 and a musical instrument peripheral manual interfaces 312-2, 312-3, . . . , 312-N will not change the position of the musical instrument amplifier actuators 304 and the musical instrument peripheral actuators 314-1 while the musical instrument amplification system 320 is energized. The settings of the musical instrument amplifier 300, position of musical instrument amplifier actuators 304, and/or musical instrument amplification manual interface 302, can change to correspond to the current position of the musical instrument peripheral actuators 314-1 and the musical instrument peripheral manual interface 312-1. Likewise, the settings of the musical instrument peripherals 310-2, 310-3, . . . , 310-N, position of musical instrument peripheral actuators 314-2, 314-3, . . . , 314-N, and/or musical instrument peripheral manual interfaces 312-2, 312-3, . . . , 312-N, can change to correspond to the current position of the musical instrument peripheral actuators 314-1 and the musical instrument peripheral manual interface 312-1.

The musical instrument amplification system 320 decreases the resistance to movement of the one or more musical instrument amplifier actuators 304 and/or musical instrument peripheral actuators 314 from the second musical instrument amplifier and/or peripheral actuator resistance to the first musical instrument amplifier and/or peripheral actuator resistance in response to the one or more musical instrument amplifier actuators 304 and/or musical instrument peripheral actuators 314 being in the first musical instrument amplifier and/or peripheral actuator position or the second musical instrument amplifier and/or peripheral actuator position for a certain amount of time. After the certain amount of time has passed, the musical instrument amplification system 320 can be de-energized. As used herein, the term “de-energized” refers to removing the power that was supplied to the musical instrument amplifier actuators 304 and musical instrument peripheral actuators 314 while the musical instrument amplification system 320 was energized. After the musical instrument amplification system 320 is de-energized, the resistance to movement of the musical instrument amplifier actuators 304, the musical instrument amplifier manual interface 302, the musical instrument peripheral actuators 314, and the musical instrument peripheral manual interfaces 312 will decrease to the level of resistance to movement before the musical instrument amplification system 320 was energized. Therefore, after the certain amount of time has passed, subsequent inputs into a musical instrument amplifier manual interface 302 and/or a musical instrument peripheral manual interface 312 can change the position of the musical instrument amplifier actuators 304 and/or the position of the musical instrument peripheral actuators 314. This process of energizing and de-energizing the musical instrument amplification system 320 can prioritize inputs to the musical instrument amplifier manual interfaces 302 and the musical instrument peripheral manual interfaces 312 such that the musical instrument amplification system 320 changes settings in response to one input at a time.

In some embodiments, the musical instrument peripherals 310 can be one or more guitars instead of foot pedals. In these embodiments, the musical instrument peripheral manual interfaces 312-2 can be the strings knobs, dials, switches, levers, or strings of the musical instrument peripherals 310-2 and the manual interface input can be a user manipulating the knobs, dials, switches, levers, or strumming the strings of the musical instrument peripheral manual interface 312-2. Manual interface inputs into manual interfaces 312-2 can cause the musical instrument amplification system 320 to energize and de-energize the same way that a manual interface input into the manual interface 312-1 can cause the musical instrument amplification system 320 to energize and de-energize.

In some embodiments, the musical instrument peripheral 310-3 can be one or more keyboards. In these embodiments, the musical instrument peripheral manual interfaces 312-3 can be the keys, buttons, switches, knobs, surfaces, or levers (e.g., joysticks) of the musical instrument peripheral 310-3 (e.g., keyboard) and the manual interface input can be a user manipulating (e.g., pressing, flipping, moving, etc.) the buttons, switches, knobs, surfaces, levers, or keys of the musical instrument peripheral manual interface 312-3. Inputs into the musical instrument peripheral manual interfaces 312-3 can cause the musical instrument amplification system 320 to energize and de-energize similarly to how inputs into the other musical instrument manual interfaces 312-1, 312-2, and 312-N can cause the musical instrument amplification system 320 to energize and de-energize. Further, musical instrument peripherals 310 can include other musical instruments and/or musical instrument manual interfaces including, but not limited to, drums, computers, smart phones, tablets, mixing boards, Musical Instrument Device Interface (MIDI) controllers, etc.

In some embodiments, the one or more musical instrument amplifier actuators 304 can change from a first musical instrument amplifier actuator position to a second musical instrument amplifier actuator position, or a musical instrument amplifier setting can change from a first musical instrument amplifier setting to a second musical instrument amplifier setting, or both, when the one or more musical instrument amplifier manual interfaces 302 change from a first musical instrument amplifier manual interface position to a second musical instrument amplifier manual interface position. Changing the musical instrument amplifier manual interface 302 from a first musical instrument amplifier manual interface position to a second musical instrument amplifier manual interface position can energize the musical instrument amplification system 320. As stated above, the musical instrument amplification system 320 can increase a resistance to movement of the one or more musical instrument peripheral actuators 314 from a first musical instrument peripheral actuator resistance to movement to a second musical instrument peripheral actuator resistance to movement in response to the musical instrument amplifier manual interface 302 energizing the musical instrument amplification system 320. After a certain amount of time has passed, the musical instrument amplification system 320 can be de-energized.

Although specific embodiments have been illustrated and described herein, those of ordinary skill in the art will appreciate that an arrangement calculated to achieve the same results can be substituted for the specific embodiments shown. This disclosure is intended to cover adaptations or variations of a number of embodiments of the present disclosure. It is to be understood that the above description has been made in an illustrative fashion, and not a restrictive one. Combinations of the above embodiments, and other embodiments not specifically described herein will be apparent to those of ordinary skill in the art upon reviewing the above description. The scope of a number of embodiments of the present disclosure includes other applications in which the above structures and methods are used. Therefore, the scope of a number of embodiments of the present disclosure should be determined with reference to the appended claims, along with the full range of equivalents to which such claims are entitled.

In the foregoing Detailed Description, some features are grouped together in a single embodiment for the purpose of streamlining the disclosure. This method of disclosure is not to be interpreted as reflecting an intention that the disclosed embodiments of the present disclosure have to use more features than are expressly recited in each claim. Rather, as the following claims reflect, inventive subject matter lies in less than all features of a single disclosed embodiment. Thus, the following claims are hereby incorporated into the Detailed Description, with each claim standing on its own as a separate embodiment.

What is claimed is:

1. A musical instrument amplification apparatus, comprising:
a musical instrument amplifier, comprising:
a manual interface configured to adjust one or more actuators of the musical instrument amplifier, settings of the musical instrument amplifier, or both;
communication circuitry configured to:
receive an input communication signal from an external device to adjust the one or more musical instrument amplifier actuators; and
send an output communication signal from the musical instrument amplifier to the external device in response to receipt of the input communication signal and/or a manual interface input; and
control circuitry configured to adjust the one or more musical instrument amplifier actuators, the setting of the musical instrument amplifier, or both, based on the input communication signal, wherein:
adjusting the one or more musical instrument amplifier actuators adjusts one or more external device actuators; and
adjusting the one or more external device actuators adjusts the one or more musical instrument amplifier actuators.

2. The musical instrument amplification apparatus of claim 1, wherein the external device comprises one or more foot pedals.

3. The musical instrument amplification apparatus of claim 1, wherein the one or more musical instrument amplifier actuators adjust settings of the musical instrument amplifier.

4. The musical instrument amplification apparatus of claim 1, wherein sensors are configured to monitor a position of the one or more musical instrument amplifier actuators, the position of the one or more manual interfaces, or both.

5. The musical instrument amplification apparatus of claim 1, wherein the manual interface comprises one or more knobs associated with each of the one or more musical instrument amplifier actuators.

6. The musical instrument amplification apparatus of claim 5, wherein at least one of the knobs changes from a first position to a second position in response to receipt of the input communication signal.

7. The musical instrument amplification apparatus of claim 5, wherein a manual interface input changes at least one of the knobs from a first position to a second position.

8. The musical instrument amplification apparatus of claim 7, wherein:
the musical instrument amplifier generates an output communication signal in response to receiving the manual interface input; and
the musical instrument amplifier sends the output communication signal to the external device.

9. The musical instrument amplification apparatus of claim 8, wherein a position sensor is configured to monitor a position of the manual interface, the one or more musical instrument actuators, or a setting of the musical instrument amplifier, or any combination thereof.

10. An apparatus, comprising:
a musical instrument peripheral, comprising:
a manual interface configured to adjust one or more musical instrument peripheral actuators, a setting of the musical instrument peripheral, or both, wherein the one or more musical instrument peripheral actuators are configured to adjust a position of the musical instrument peripheral, the setting of the musical instrument peripheral, or both based on a manual interface input;
communication circuitry configured to:
send an output communication signal from the musical instrument peripheral to an external device; and
receive an input communication signal from the external device to adjust the one or more musical instrument peripheral actuators, the setting of the musical instrument peripheral, or both; and
control circuitry configured to adjust the one or more musical instrument peripheral actuators, the setting of the musical instrument peripheral, or both, wherein:
adjusting the one or more musical instrument peripheral actuators adjusts one or more external device actuators; and
adjusting the one or more external device actuators adjusts the one or more musical instrument peripheral actuators.

11. The apparatus of claim 10, wherein the external device is a musical instrument amplifier.

12. The apparatus of claim 10, wherein the manual interface is a surface of the musical instrument peripheral.

13. The apparatus of claim 10, wherein the manual interface input comprises a force applied to the manual interface.

14. The apparatus of claim 10, wherein sensors are configured to monitor the position of the one or more musical instrument peripheral actuators, the position of the one or more manual interfaces, or both.

15. The apparatus of claim 10, wherein the output communication signal is sent from the musical instrument peripheral to the external device in response to receipt of the manual interface input.

16. A musical instrument amplification system, comprising:
a musical instrument peripheral coupled to a musical instrument amplifier, wherein the musical instrument peripheral comprises:
one or more musical instrument peripheral actuators configured to adjust a position of the musical instrument peripheral, a setting of the musical instrument peripheral, or both, based on a musical instrument peripheral manual interface input received by a musical instrument peripheral manual interface;
musical instrument peripheral communication circuitry configured to:
receive, from the musical instrument amplifier, an input communication signal for the musical instrument peripheral to adjust the position of the musical instrument peripheral manual interface, a setting of the musical instrument peripheral, or both; and
send an output communication signal from the musical instrument peripheral to the musical instrument amplifier to adjust a position of a musical instrument amplifier manual interface, a setting of the musical instrument amplifier, or both; and
control circuitry configured to adjust the position of the musical instrument peripheral based on the input communication signal; and
the musical instrument amplifier, comprising:
the musical instrument amplifier manual interface configured to adjust one or more musical instrument amplifier actuators, or settings of the musical instrument amplifier, or both;
musical instrument amplifier communication circuitry configured to:
receive an input communication signal from the musical instrument peripheral for the musical instrument amplifier to adjust the position of the musical instrument amplifier manual interface, a setting of the musical instrument amplifier, or both; and
send an output communication signal from the musical instrument amplifier to the musical instrument peripheral to adjust the position of the musical instrument peripheral, a setting of the musical instrument peripheral, or both; and
musical instrument amplifier control circuitry configured to adjust the position of the musical instrument amplifier manual interface based on the input communication signal.

17. The musical instrument amplification system of claim 16, wherein the musical instrument peripheral is coupled to the musical instrument amplifier by electrical wiring or wireless communication.

18. The musical instrument amplification system of claim 16, wherein the one or more musical instrument amplifier actuators are coupled to the musical instrument amplifier manual interface such that movement of the musical instrument amplifier actuators corresponds to movement of the musical instrument amplifier manual interface and the movement of the musical instrument amplifier manual interface corresponds to the movement of the musical instrument amplifier actuators.

19. The musical instrument amplification system of claim 16, wherein the one or more musical instrument peripheral actuators are coupled to the musical instrument peripheral manual interface such that movement of the one or more musical instrument peripheral actuators corresponds to movement of the musical instrument peripheral manual interface and the movement of the musical instrument peripheral manual interface corresponds to the movement of the one or more musical instrument peripheral actuators.

20. The musical instrument amplification system of claim 16, wherein the one or more musical instrument peripheral actuators change from a first musical instrument peripheral actuator position to a second musical instrument peripheral actuator position when the one or more musical instrument amplifier actuators change from a first musical instrument amplifier actuator position to a second musical instrument amplifier actuator position, or a musical instrument amplifier setting changes from a first musical instrument amplifier setting to a second musical instrument amplifier setting, or both.

21. The musical instrument amplification system of claim 16, wherein the one or more musical instrument amplifier actuators change from a first musical instrument amplifier actuator position to a second musical instrument amplifier actuator position, or a musical instrument amplifier setting changes from a first musical instrument amplifier setting to a second musical instrument amplifier setting, or both, when the one or more musical instrument peripheral actuators change from a first musical instrument peripheral actuator position to a second musical instrument peripheral actuator position.

22. The musical instrument amplification system of claim 16, wherein changing the one or more musical instrument peripheral actuators from a first musical instrument peripheral actuator position to a second musical instrument peripheral actuator position energizes the musical instrument amplification system.

23. The musical instrument amplification system of claim 22, wherein the musical instrument amplification system increases a resistance to movement of the one or more musical instrument amplifier actuators from a first musical instrument amplifier actuator resistance to a second musical instrument amplifier actuator resistance in response to the one or more musical instrument peripheral actuators energizing the musical instrument amplification system.

24. The musical instrument amplification system of claim 23, wherein the musical instrument amplification system decreases the resistance to movement of the one or more musical instrument amplifier actuators from the second musical instrument amplifier actuator resistance to the first musical instrument amplifier actuator resistance in response to the one or more musical instrument peripheral actuators being in the first musical instrument peripheral actuator position or the second musical instrument peripheral actuator position for a certain amount of time.

25. The musical instrument amplification system of claim 16, wherein changing the musical instrument amplifier manual interface from a first musical instrument amplifier manual interface position to a second musical instrument amplifier manual interface position energizes the musical instrument amplification system.

26. The musical instrument amplification system of claim 25, wherein the musical instrument amplification system increases a resistance to movement of the one or more musical instrument peripheral actuators from a first musical instrument peripheral actuator resistance to a second musical instrument peripheral actuator resistance in response to the musical instrument amplifier manual interface energizing the musical instrument amplification system.

27. The musical instrument amplification system of claim 26, wherein the musical instrument amplification system decreases the resistance to movement of the one or more musical instrument peripheral actuators from the second musical instrument peripheral actuator resistance to the first musical instrument peripheral actuator resistance in response to the one or more musical instrument amplifier actuators being in the first musical instrument amplifier actuator position or the second musical instrument amplifier actuator position for a certain amount of time.
